(19) United States
(12) Patent Application Publication
(10) Pub. No.: US 2014/0338599 A1
(43) Pub. Date: Nov. 20, 2014

(54) EVAPORATOR AND THIN FILM DEPOSITION SYSTEM INCLUDING THE SAME

(71) Applicant: Samsung Display Co., Ltd., Yongin-city (KR)

(72) Inventor: Hyun-Seok KIM, Yongin-city (KR)

(73) Assignee: Samsung Display Co., Ltd., Yongin-city (KR)

(21) Appl. No.: 14/014,982

(22) Filed: Aug. 30, 2013

(30) Foreign Application Priority Data
May 15, 2013 (KR) 10-2013-0055278

(51) Int. Cl. H01L 51/56

(52) U.S. Cl. CPC H01L 51/56
USPC 118/721; 118/726; 432/197; 392/386

(57) ABSTRACT

The present invention relates to an evaporator and a thin film deposition system including the same. The evaporator according to an exemplary embodiment of the present invention includes a container including an evaporation space, a heater configured to heat the container, an inflow part configured to spray a liquid raw material into the evaporation space, and a rotor disposed in the evaporation space, the rotor configured to evaporate the liquid raw material.

### CROSS-REFERENCE TO RELATED APPLICATION

This application claims priority from and the benefit of Korean Patent Application No. 10-2013-0055278, filed on May 15, 2013, which is hereby incorporated reference for all purposes as if fully set forth herein.

### BACKGROUND

1. Field

Exemplary embodiments of the present invention relate to an evaporator and a thin film deposition system including the same, and more particularly, to an evaporator having improved evaporation efficiency.

2. Background

An organic light emitting display apparatus is a display apparatus including an organic light emitting device (OLED) which itself emits light, to display an image, and may be driven at a low voltage direct current, have a fast response speed, have a wide use temperature range, and the like. However, the organic light emitting display apparatus may be easily permeated by external moisture or oxygen, and deteriorate accordingly. Thus, packaging technology for encapsulating the organic light emitting device may help avoid these problems.

In the packaging technology for an organic light emitting display apparatus, thin film encapsulation technology may be used to implement flexible organic light emitting display apparatuses. Thin film encapsulation technology involves alternately stacking one or more layers of an inorganic film and an organic film and then covering a display region of a substrate with a thin film encapsulation layer.

The organic film may be formed by, for example, flash evaporation. That is, the organic film may be formed by spraying a liquid raw material, which forms the organic film, into an evaporator. Then, the sprayed liquid raw material is evaporated, and then the evaporated material is deposited on the upper surface of a substrate.

However, liquid raw material that has not been evaporated due to continuous spraying of the liquid raw material may accumulate and cause the liquid raw material to be cured in the evaporator. When the liquid raw material is cured in the evaporator, the evaporator may become contaminated and the efficient evaporation of the liquid raw material to be sprayed thereafter impeded. Thus, there may be variation in the amount of the liquid raw material subsequently evaporated. Further, the cured raw material in the evaporator is formed as solid particles and may adhere to the substrate, thereby causing the quality of the thin film encapsulation to deteriorate.

### SUMMARY

Exemplary embodiments of the present invention provide an evaporator having improved evaporation efficiency and a thin film deposition system including the same.

Additional features of the invention will be set forth in the description which follows, and in part will be apparent from the description, or may be learned by practice of the invention.

An exemplary embodiment of the present invention discloses an evaporator including a container including an evaporation space, a heater configured to heat the container, an inflow part configured to spray a liquid raw material into the evaporation space, and a rotor disposed in the evaporation space, the rotor configured to evaporate the liquid raw material.

According to another exemplary embodiment of the present invention, a thin film deposition system includes a chamber and an evaporator configured to supply an evaporated raw material to the chamber. The evaporator includes a container including an evaporation space, a heater configured to heat the container, an inflow part configured to spray a liquid raw material into the evaporation space, and a rotor disposed in the evaporation space, the rotor configured to evaporate the liquid raw material.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 a cross-sectional view schematically illustrating the thin film deposition system according to an exemplary embodiment of the present invention.

FIG. 2 is a cross-sectional view illustrating an evaporator of the thin film deposition system of FIG. 1.

FIGS. 3 and 4 are cross-sectional views illustrating modified examples of the evaporator of FIG. 2.

FIG. 5 is a cross-sectional view schematically illustrating an organic light emitting display apparatus manufactured using the thin film deposition system of the present exemplary embodiment.

FIG. 6 is an enlarged view of section “F” of FIG. 5.

### DETAILED DESCRIPTION OF THE ILLUSTRATED EMBODIMENTS

Since the present invention may have various embodiments by making various modifications thereto, specific embodiments will be illustrated in the drawings and described in detail in the detailed description. However, this does not limit the present invention to specific exemplary embodiments, and it should be understood that the present invention covers all the modifications, equivalents and replacements within the idea and technical scope of the present invention. In describing the present invention, when it is determined that a detailed description of related well-known technology may obscure the gist of the present invention, the detailed description thereof will be omitted.

Further, in each drawing, constituent elements are exaggerated or omitted for the convenience and clarity of explanation, and the size of each constituent element does not accurately reflect the actual size. In addition, when an constituent element is referred to as being “on” or “under” another constituent element, the constituent element can be directly “on” or “under” another constituent element or intervening constituent elements may be present, and the criteria regarding on and under will be described based on the drawings.

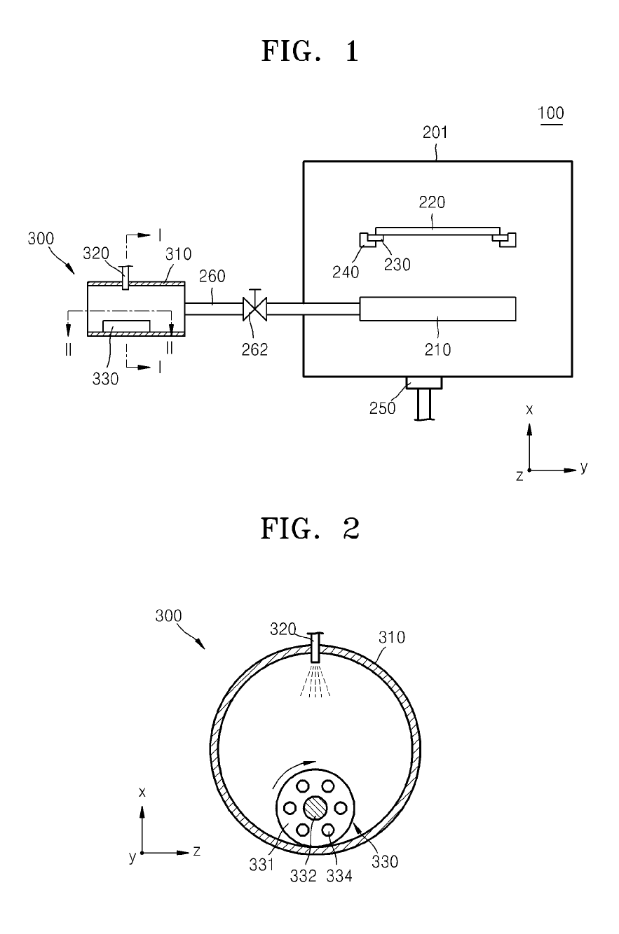

FIG. 1 is a cross-sectional view schematically illustrating a thin film deposition system 100 according to an exemplary embodiment of the present invention, and FIG. 2 is a cross-sectional view illustrating an evaporator 300 of the thin film deposition system 100 of FIG. 1. More specifically, FIG. 2 is a cross-sectional view illustrating a cross section along line I-I of FIG. 1, and is a cross-sectional view in the y-direction and corresponding to the x-z plane.

Referring to FIGS. 1 and 2, the thin film deposition system 100 according to the present exemplary embodiment may include a process chamber 201 which forms a space for a deposition process and the evaporator 300 which supplies an evaporated raw material to the process chamber 201. The evaporator 300 and the process chamber 201 may be connected with each other by a transfer tube 260.

A substrate 220 on which a thin film is deposited, a mask 230 that is disposed on the surface of the substrate 220 on which the thin film is deposited, a frame part 240 which supports the substrate 220 and the mask 230, and a nozzle part 210 that sprays the evaporated raw material onto the substrate 220 may be disposed in the process chamber 201. Further, the process chamber 201 may further include a pump 250 for creating a vacuum and exhausting the process chamber 201, an alignment system (not illustrated) for arranging the substrate 220 and the mask 230, and the like.

The evaporator 300 may include a container such as a barrel 310, a heater (not illustrated) that heats the barrel 310, an inflow part 320 which introduces the liquid raw material into an evaporation space of the evaporator 300, and a rotor 330 that is disposed in the evaporation space.

The barrel 310 provides an internal space in which a liquid raw material is evaporated, and may have various shapes such as a cylindrical shape or polyprism shape having an empty space therein. In addition, the internal surface of the barrel 310 directly exposed to the liquid raw material or evaporated raw material prevents damage and the like caused by corrosion or friction, and may have a detachable metal layer coupled thereto in order to improve the transfer efficiency of heat generated by the heater.

An inlet gas line (not illustrated), which supplies the liquid raw material and a carrier gas such as argon (Ar), is connected to one side of the barrel 310. A discharge port (not illustrated), from which the evaporated liquid raw material and the carrier gas are discharged, is formed on the other side of the barrel 310. The inlet gas line is connected to an inflow part 320, and the discharge port is connected to the transfer tube 260.

The inflow part 320 is formed to pass through the top of the barrel 310, and may spray the liquid raw material to the internal space of the barrel 310 by using an included supersonic nozzle or Venturi nozzle. Meanwhile, the liquid raw material may be a raw material for forming an organic film on the substrate 220. For example, the liquid raw material may be acrylate-based, silicone-based, epoxy-based, allyl-based and the like, but is not limited thereto.

The heater is formed on the peripheral surface of the barrel 310 and thus heats the barrel 310. The heater may consist of a heating coil around the peripheral surface of the barrel 310 or a heating jacket surrounding the peripheral surface of the barrel 310, but is not limited thereto. Meanwhile, the heater may also be formed on the internal surface of the barrel 310, that is, in the evaporation space and may also be formed simultaneously on the internal and external surfaces.

When the barrel 310 is heated by the heater, the liquid raw material sprayed by the inflow part 320 is evaporated from the evaporation space and the discharge port discharges the evaporated liquid raw material to the outside of the barrel 310. The discharge port is connected to the transfer tube 260, and a valve 262 is disposed along the transfer tube 260 to control the amount of the evaporated liquid raw material introduced into the process chamber 201.

Meanwhile, since the inflow part 320 passes through the top of the barrel 310, the formation position thereof may be fixed. Further, since the liquid raw material sprayed through the inflow part 320 falls to the lower portion of the barrel 310 due to gravity, the liquid raw material may collect at a specific region of the bottom of the barrel 310. When the liquid raw material is disposed so that it falls on the specific region as described above, the evaporation efficiency is reduced, and thus the liquid raw material may be cured in the barrel 310 instead of evaporating.

If the liquid raw material is collected at a position where the rotor 330 is disposed, the above-described problem may be solved and the evaporation efficiency of the evaporator 330 may be improved. For example, the rotor 330 may be disposed to correspond to the position of the inflow part 320 at the lower portion of the barrel 310.

As illustrated in FIG. 2, the rotor 330 may include a body 331, a central shaft 332 for rotating the body 331, and a plurality of heating lines 334 which are disposed in the body 331.

The body 331 may be formed longitudinally along one direction of the barrel 310, and may be formed of a metal material having excellent heat transfer rate characteristics, such as copper. The body 331 may have a cylindrical shape, for example, but is not limited thereto.

The central shaft 332 may be formed parallel with and horizontally to the extending direction of the body 331, one end thereof may be connected to an external motor (not illustrated), and the other end thereof may be coupled to the body 331. Thus, when the central shaft 332 is rotated by the driving of the external motor, the body 331 may also be rotated with respect to the central shaft 332.

The heating line 334 heats the body 331, and a power source line (not illustrated) for supplying power may be connected to the heating line 334.

When the liquid raw material is sprayed from the inflow part 320, the rotor 330 may be rotated to evaporate the liquid raw material.

More specifically, when the liquid raw material sprayed from the inflow part 320 comes into contact with the surface of the body 331 of the rotor 330, it evaporates. Meanwhile, the rotor 330 is disposed at a position toward which the liquid raw material collects, and is configured to rotate. As a result, the body 331 continuously provides a new surface portion thereof to evaporate the liquid raw material. For example, the rotor 330 may be configured so that it is rotated once while the inflow part 320 sprays the liquid raw material for a single period of time.

Therefore, although the liquid raw material collects at the region in which the rotor 330 is disposed, the surface portion of the body 331 from which the liquid raw material is evaporated is continuously replaced with a new surface portion, and thus the evaporation efficiency of the evaporator 300 may be improved. Meanwhile, although not illustrated in the drawings, projections or grooves may be formed on the surface of the body 331 to increase the contact surface area with the liquid raw material.

In addition, when the liquid raw material is sprayed from the inflow part 320, the rotor 330 may be rotated so that liquid raw material that collects at a specific region may be dispersed. As a result, more of the liquid raw material may be evaporated and the accumulation of liquid raw material may be prevented. Therefore, since a curing phenomenon of the liquid raw material is reduced, the contamination of the transfer tube 260 and the like may be also be reduced. In addition, the amount of time between each cleaning cycle of the parts of the thin film deposition system 100 may be extended.

Thus, according to exemplary embodiments of the present invention, the evaporation efficiency of the evaporator may be improved. Furthermore, it is possible to reduce the contamination of a transfer tube and the like, which connect the evaporator with the process chamber, thereby extending the amount of time per cleaning cycle of parts of the thin film deposition system.

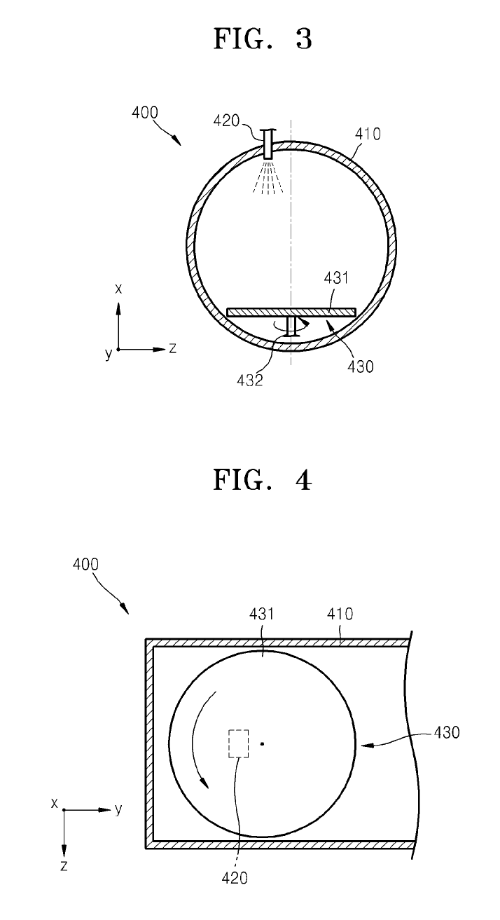

FIGS. 3 and 4 are cross-sectional views illustrating modified examples of the evaporator of FIG. 2, according to additional exemplary embodiments. FIG. 3 is a cross-sectional view illustrating the cross section along line I-I of FIG. 1, in the y-direction and corresponding to the x-z plane, and FIG. 4 is a plan view illustrating the cross section along line II-II of FIG. 1, in the x-direction and corresponding to the y-z plane.

Referring to FIGS. 3 and 4, an evaporator 400 may include a barrel 410, a heater (not illustrated) which heats the barrel 410, an inflow part 420 that introduces the liquid raw material into the evaporation space, and a rotor 430 that is disposed in the evaporation space.

The barrel 410, the heater, and the inflow part 420 are substantially the same as the equivalent features illustrated and described in FIGS. 1 and 2 and thus will not be repeatedly described.

A rotor 430 includes a body 431 and a rotation shaft 432 for rotating the body 431, and the rotor 430 is disposed at the lower portion of the inflow part 420, and thus may evaporate the liquid raw material sprayed from the inflow part 420.

The body 431 may have a plate shape with a flat top. However, the present invention is not limited thereto, and the shape of the body 431 is sufficient as long as the body 431 has a structure in which it may be rotated with respect to the rotation shaft 432 while maintaining a horizontal level as described below. For example, the rotor 430 may also have a mushroom-like shape.

The body 431 may be formed of a material having excellent thermal conductivity, such as copper. The bottom of the body 431 may be coupled to the rotation shaft 432, thus allowing the body 431 to be rotated along with the rotation of the rotation shaft 432.

The rotation shaft 432 may be formed in a vertical direction, and may be connected to a motor (not illustrated) and the like, which is disposed outside of the evaporator 400.

In addition, the rotor 430 may further include a heater (not illustrated) which heats the body 431. The heater may be, for example, a heating wire which is disposed in the body 431, or a heating plate which is in contact with a surface of the body 431. Further, the heater may also be formed entirely over the body 431, or may be formed on a part of the body 431.

When the liquid raw material is sprayed from the inflow part 420, the rotor 430 may be rotated to evaporate the liquid raw material. For example, the rotor 430 may be set to be rotated once during a single spraying of the liquid raw material by the inflow part 320.

In addition, the inflow part 420 may be disposed to deviate from the extension line of the rotation shaft 432 in one direction in order to improve evaporation. That is, since the inflow part 420 is offset from the extension line of the rotation shaft 432, the liquid raw material sprayed from the inflow part 420 may collect at a region of the surface of the body 431 which extends from the central portion of the body 431 to a corner of the body 431, rather than collecting at the central portion of the body 431.

As described above, if the rotor 430 is rotated while the inflow part 420 sprays the liquid raw material, the body 431 may continuously provide a new surface portion thereof to evaporate the liquid raw material. Thus, it is possible for the entirety of the liquid raw material to be uniformly dispersed over the top of the body 431, thereby improving the evaporation efficiency of the evaporator 400. Further, it is possible to prevent the liquid raw material which has not been cured from accumulating in one place, thereby reducing the curing of the liquid raw material in the barrel 410.

In addition, although not illustrated in the drawings, the rotor 430 may further include a blade that may clean the top of the body 431. With regard to a region that the inflow part 420 collects toward when spraying the liquid raw material, the blade may be disposed on a side opposite to said region. Therefore, the raw material cured at the top of the body 431 may be removed, with each rotation of the body 431.

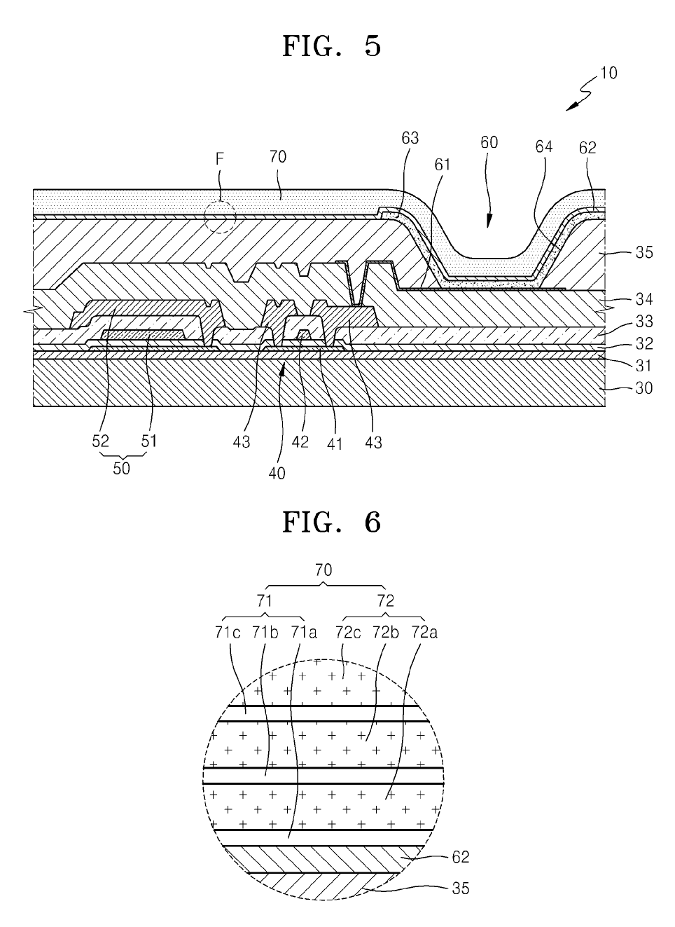

FIG. 5 is a cross-sectional view schematically illustrating an organic light emitting display apparatus manufactured by using a sputtering apparatus according to an exemplary embodiment of the present invention, and FIG. 6 is an enlarged view of section “F” of FIG. 5.

Referring to FIGS. 5 and 6, an organic light emitting display apparatus is formed on a substrate 30. The substrate 30 may be formed of a glass material, a plastic material, or a metal material.

A buffer layer 31, which provides a flat surface on the upper portion of the substrate 30 and contains an insulation material in order to prevent moisture and impurities from permeating into the substrate 30, is formed on the substrate 30.

A thin film transistor (TFT) 40, a capacitor 50, and an organic light emitting device 60 are formed on the buffer layer 31. The thin film transistor 40 includes an active layer 41, a gate electrode 42, and a source/drain electrode 43. The organic light emitting device 60 includes a first electrode 61, a second electrode 62, and an intermediate layer 63. The capacitor 50 includes a first capacitor electrode 51 and a second capacitor electrode 52.

Specifically, the active layer 41 is formed to have a predetermined pattern and is disposed on the upper surface of the buffer layer 31. The active layer 41 may contain an inorganic semiconductor material such as silicon, an organic semiconductor material, or an oxide semiconductor material, and may also be formed by selectively injecting a p-type or n-type dopant thereinto.

A gate insulation layer 32 is formed on the upper portion of the active layer 41. The gate electrode 42 is formed to correspond to the active layer 41 on the upper portion of the gate insulation layer 32. The first capacitor electrode 51 may be formed on the upper portion of the gate insulation layer 32, and may be formed of a material which is the same as that of the gate electrode 42.

An inter-layer dielectric 33 is formed so as to cover the gate electrode 42, and the source/drain electrode 43 is formed on the inter-layer dielectric 33 and is formed to be in contact with a predetermined region of the active layer 41. The second capacitor electrode 52 may be formed on the insulation layer 33, and may be formed of a material which is the same as that of the source/drain electrode 43.

A passivation layer 34 is formed so as to cover the source/drain electrode 43, and a separate insulation layer (not shown) may be further formed on the upper portion of the passivation layer 34 for planarizing the thin film transistor 40.

The first electrode 61 is formed on the passivation layer 34. The first electrode 61 is formed so as to be electrically connected to one of the source/drain electrode 43. Moreover, a pixel definition film 35 is formed so as to cover the first electrode 61. A predetermined opening 64 is formed in the pixel definition film 35, and then the intermediate layer 63 including an organic light emitting layer is formed in a region that is limited by the opening 64. The second electrode 62 is formed on the intermediate layer 63.

An encapsulation layer 70 is formed on the second electrode 62. The encapsulation layer 70 may contain an organic material or inorganic material, and may have a structure in which the organic material and the inorganic material are alternately stacked.

For example, the encapsulation layer 70 may be formed using the thin film deposition system 100 described above with reference to FIG. 1. That is, the substrate 30 on which the second electrode 62 is formed is introduced into the process chamber 201, and then a desired layer may be formed by using the thin film deposition system 100.

In particular, the encapsulation layer 70 includes an inorganic layer 71 and an organic layer 72. The inorganic layer 71 includes a plurality of layers 71a, 71b, and 71c, and the organic layer 72 includes a plurality of layers 72a, 72b, and 72c. At this time, a plurality of layers 72a, 72b, and 72c of the organic layer 72 may be formed by using the thin film deposition system 100.

However, the present invention is not limited thereto. That is, it is also possible to form other constituent elements such as the intermediate layer 63 of the organic light emitting display apparatus 10 by using the thin film deposition system 100.

In the evaporator according to exemplary embodiments of the present invention and the thin film deposition system including the same, the configuration and method of the exemplary embodiments described above may not be limited in their application, but the exemplary embodiments may be configured by selectively combining all or a part of each embodiment such that various modifications may be made.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An evaporator comprising:
a container comprising an evaporation space;
a heater configured to heat the container;
an inflow part configured to spray a liquid raw material into the evaporation space; and
a rotor disposed in the evaporation space, the rotor configured to evaporate the liquid raw material.

2. The evaporator of claim 1, wherein the inflow part passes through a first portion of the container, and the rotor is disposed on a second portion of the container opposite to the first portion,
wherein the position of the rotor corresponds with the position of the inflow part.

3. The evaporator of claim 2, wherein the rotor comprises:
a body;
a shaft configured to rotate the body; and
heating elements disposed in the body,
wherein the heating elements are configured to heat the body.

4. The evaporator of claim 3, wherein the shaft is disposed parallel with and horizontally to the extending direction of the body.

5. The evaporator of claim 4, wherein the body comprises a cylindrical shape, and is configured to be rotated with respect to the shaft.

6. The evaporator of claim 3, wherein the inflow part is configured to spray the liquid raw material for a first period of time in response to a rotation of the rotor.

7. The evaporator of claim 3, wherein the body comprises a surface comprising projections or grooves.

8. The evaporator of claim 2, wherein the rotor comprises:
a body; and
a rotation shaft coupled to a first side of the body, the rotation shaft configured to rotate the body,
wherein the rotation shaft is disposed in a direction vertical to the extending direction of the body.

9. The evaporator of claim 8, wherein the inflow part is offset from an imaginary line that extends along the extension direction of the rotation shaft.

10. The evaporator of claim 9, wherein the body comprises a circular plate shape.

11. The evaporator of claim 8, wherein the rotor comprises a mushroom-like shape.

12. The evaporator of claim 8, wherein the rotor further comprises a heater configured to heat the body.

13. A thin film deposition system, comprising:
a chamber; and
an evaporator configured to supply an evaporated raw material to the chamber,
wherein the evaporator comprises:
a container comprising an evaporation space;
a heater configured to heat the container;
an inflow part configured to spray a liquid raw material into the evaporation space; and
a rotor disposed in the evaporation space, the rotor configured to evaporate the liquid raw material.

14. The thin film deposition system of claim 13, wherein the inflow part passes through a first portion of the container, and the rotor is disposed on a second portion of the container opposite to the first portion,
wherein the position of the rotor corresponds with the position of the inflow part.

15. The thin film deposition system of claim 13, wherein the inflow part is configured to spray the liquid raw material for a first period of time in response to a rotation of the rotor.

16. The thin film deposition system of claim 13, wherein the rotor comprises:
a cylindrical body;
a shaft disposed at the center of the cylindrical body. the shaft configured to rotate the cylindrical body; and
heating elements disposed in the cylindrical body,
wherein the heating elements are configured to heat the cylindrical body.

17. The thin film deposition system of claim 13, wherein the rotor comprises:
a body; and
a rotation shaft coupled to a first side of the body, the rotation shaft configured to rotate the body,
wherein the rotation shaft is disposed in a direction vertical to the extending direction of the body.

18. The thin film deposition system of claim 17, wherein the inflow part is offset from an imaginary line that extends along to extension direction of the rotation shaft.

19. The thin film deposition system of claim 17, wherein the rotor further comprises a blade configured to clean a second side of the body opposite to the first side.

20. The thin film deposition system of claim 13, wherein the chamber comprises:
a frame part supporting a substrate and a mask; and
a nozzle part configured to spray the evaporated raw material onto the substrate.
